(19) United States
(12) Patent Application Publication
(10) Pub. No.: US 2006/0043480 A1
(43) Pub. Date: Mar. 2, 2006

(54) Semiconductor device and fabrication method of the same

(75) Inventors: Masanobu Tsuchitani, Kawasaki-shi (JP); Tetsuo Matsuda, Yokohama-shi (JP); Hideki Okumura, Yokohama-shi (JP); Atsuko Yamashita, Yokosuka-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/991,433

(22) Filed: Nov. 19, 2004

(30) Foreign Application Priority Data
Sep. 1, 2004 (JP) 2004-254467

(51) Int. Cl. H01L 29/76; H01L 21/336

(52) U.S. Cl. 257/341; 257/342; 438/306; 438/307; 257/335; 257/328; 438/268

(57) ABSTRACT

A semiconductor device comprises a semiconductor layer which includes a terminate end part and a cell formation part that is surrounded by this end part, and a plurality of guard rings each of which is formed at the end part to surround the cell formation part. These guard rings are made shallower and smaller in width as they get near to the guard ring that resides at the outside position.

### CROSS-REFERENCE TO RELATED APPLICATION(S)

This application is based upon and claims the benefit of priority from the prior Japanese Patent Application No. 2004-254467, filed on Sep. 1, 2004, the entire contents of which are incorporated herein by reference.

### BACKGROUND OF THE INVENTION

1. Field of the Invention

The present invention relates to semiconductor devices such as metal oxide semiconductor field effect transistors (MOSFETs) for the power use. This invention also relates to fabrication methodology of the same.

2. Description of the Related Art

Semiconductor devices for the power use, such as power MOSFETs, are semiconductor chips that are structured so that a large number of cells are formed in an epitaxially grown layer (semiconductor region) that is disposed on or above a semiconductor substrate while letting the gates of such cells be common-coupled together. As power MOSFETs are low in turn-on (ON) resistance and are capable of performing switching operations at high speeds, it is possible to efficiently control a large current of high frequency. Hence, power MOSFETs are widely employed as small-size power converter circuit elements for use as components of power supply units in personal computers (PCs), for example.

In power MOSFETs, a semiconductor region which couples source and drain regions together is generally called a “drift” region. At the time a power MOSFET turns on, the drift region becomes a current flow path. When the power MOSFET turns off, a depletion layer is created to extend from a p-n junction that consists of the drift region and a base region, thereby retaining the power MOSFET's breakdown voltage.

The power MOSFET typically has a cell formation part and a terminate end part that is positioned around the cell formation part. Since a lot of cells are regularly laid out in the cell formation part, the depletion layer must behave to spread uniformly. Accordingly, the curvature of such depletion layer becomes moderate or “relaxed” in the cell formation part so that a portion that experiences electric-field concentration hardly takes place. In contrast, the end part is such that the above-noted layout regularity is reduced or “collapsed” so that the depletion layer is no longer expected to spread uniformly without using any special means. This would result in occurrence of portions with steep curvatures. At such portions, electric fields are concentrated. Thus, the power MOSFET decreases in breakdown voltage. Consequently, an impurity-doped protective region, also called the guard ring, is formed at the end part in such a manner as to surround the cell formation part to make the depletion layer moderate in curvature, thereby improving the transistor breakdown voltage. Examples of this approach are found, for example, in FIG. 11 of JP-A-2000-183350 and also in FIG. 1 of JP-A-8-167714. Unfortunately, the prior known guard ring structures as taught thereby are faced with the difficulty to permit the depletion layer to sufficiently spread at the end part. Thus a need is felt to further improve the breakdown voltage.

### BRIEF SUMMARY OF THE INVENTION

According to one aspect of the present invention, there is provided a semiconductor device comprises a semiconductor layer including a terminate end part and a cell formation part as surrounded by this end part, and a plurality of guard rings each being formed at the end part to surround the cell formation part and being arranged to become shallower and smaller in width as getting near to a guard ring placed outside.

According to another aspect of the present invention, there is provided a semiconductor device comprises a semiconductor layer including a terminate end part and a cell formation part as surrounded by this end part, and a plurality of guard rings each being formed at the end part to surround the cell formation part and being made shallower and larger in interval between neighboring ones thereof as they get near to a guard ring placed outside.

According to still another aspect of the present invention, there is provided a method for fabricating a semiconductor device comprises, forming a to-be-processed film to be processed into a mask on a surface of a semiconductor layer including a terminate end part and a cell formation part as surrounded by this end part, forming at a portion of the to-be-processed film corresponding to the end part a plurality of openings surrounding a portion of the to-be-processed film corresponding to the cell formation part and being made smaller in width as they get near to an opening placed outside, selectively etching the semiconductor layer while letting the to-be-processed film with the plurality of openings formed therein be as a mask to thereby form in the end part a plurality of trenches being made shallower and smaller in width as getting near to a trench placed outside, and burying an epitaxial growth layer in the plurality of trenches to thereby form in the end part a plurality of guard rings.

### BRIEF DESCRIPTION OF THE DRAWINGS

FIG. 1 is a diagram showing a partial cross-sectional view of a cell formation part of a power semiconductor device in accordance with a first embodiment of the invention.

FIG. 2 is a partial sectional view of a terminate end part of the semiconductor device in accordance with the embodiment.

FIG. 3 is a plan view of the semiconductor device in accordance with the embodiment.

FIG. 4 is a partial sectional view of the terminate end part of a semiconductor device of a comparative form at the time this device turns off.

FIG. 5 is a partial sectional view of the terminate end part of the first embodiment at the time this device turns off.

FIG. 6 is a first process step diagram (cell formation part) of a method for fabricating the semiconductor device in accordance with the first embodiment.

FIG. 7 is a first step diagram (end part) of the semiconductor device fabrication method.

FIG. 8 is a second step diagram (cell formation part) of the device fabrication method.

FIG. 9 is a second step diagram (end part) of the fabrication method.

FIG. 10 is a third step diagram (cell formation part) of the method.

FIG. 11 is a third step diagram (end part) of the method.

FIG. 12 is a fourth step diagram (cell formation part) of the method.

FIG. 13 is a fourth step diagram (end part) of the method.

FIG. 14 is a fifth step diagram (cell formation part) of the method.

FIG. 15 is a fifth step diagram (end part) of the method.

FIG. 16 is a sixth step diagram (cell formation part) of the method.

FIG. 17 is a sixth step diagram (end part) of the method.

FIG. 18 is a diagram pictorially representing a partial cross-section of a silicon layer which exhibits micro-loading effects.

FIG. 19 is a partial sectional view of the terminate end part of a power semiconductor device in accordance with a second embodiment.

FIG. 20 is a diagram showing the state that a depletion layer extends at the end portion of FIG. 19.

### DETAILED DESCRIPTION OF THE INVENTION

Embodiments of this invention will be explained while dividing the description into sections titled “First Embodiment” and “Second Embodiment,” the former of which consists of several subsections which follow: “Semiconductor Device Structure,” “Semiconductor Device Operation,” “Main Effects of First Embodiment,” and “Semiconductor Device Fabrication Method.”

It should be noted that in the drawings for explaining respective embodiments, like parts or components are designated by like reference numerals and symbols.

### First Embodiment

A main feature of a semiconductor device in accordance with a first embodiment lies in that a plurality of guard rings are formed at a terminate end part so that these are made (1) shallower, (2) smaller in width and (3) larger in interval of neighboring guard rings as they get near to a guard ring that is located on an outer side.

(Semiconductor Device Structure)

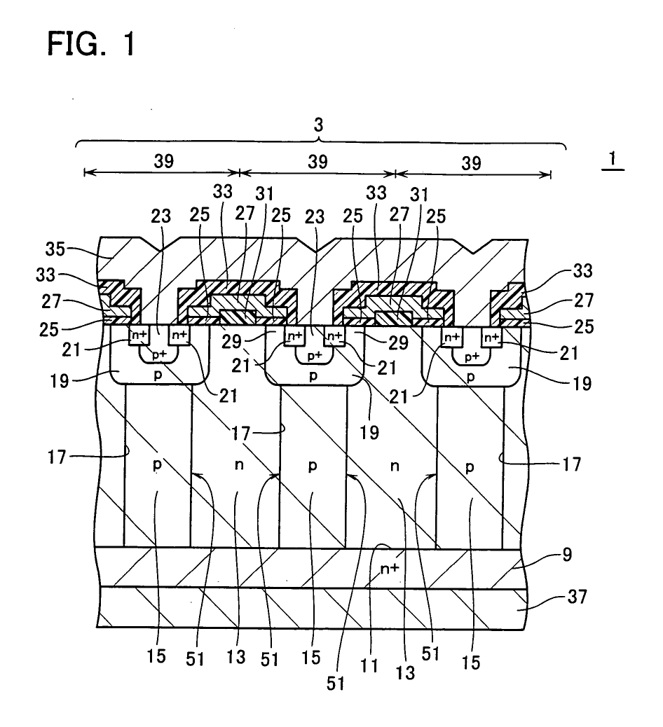

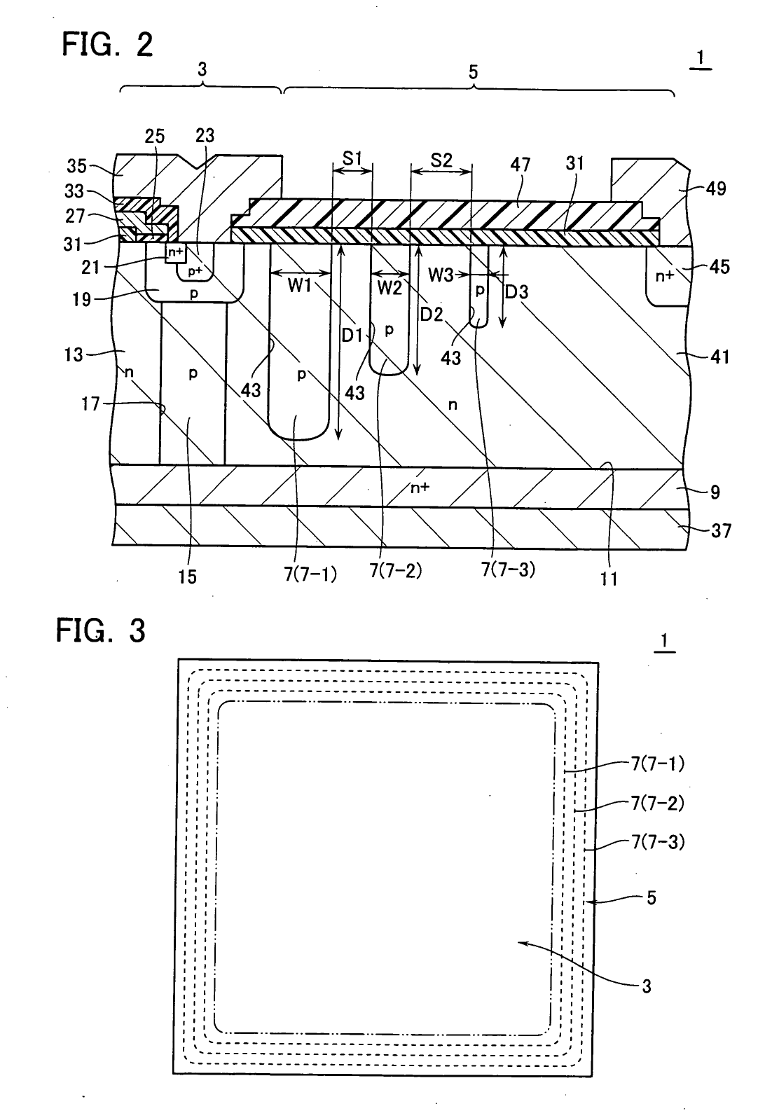

FIG. 1 is a diagram showing a partial cross-sectional view of a cell formation part 3 of a semiconductor device 1 for the power use in accordance with the first embodiment, and FIG. 2 shows a partial cross-section of a terminate end part 5 of the power semiconductor device 1. FIG. 3 depicts a plan view of the semiconductor device 1. Firstly, a planar structure of semiconductor device 1 will be explained using FIG. 3. The power semiconductor device 1 is a semiconductor chip which includes a terminate end part 5 and a cell formation part 3 as surrounded by this end part 5 In the cell formation part 3, a great number of MOSFET cells are formed although these are not shown in FIG. 3. The MOSFET cells are connected in parallel. In the end part 5, triple guard rings 7 are formed to surround the cell formation part 3.

A detailed explanation of a structure of the cell formation part 3 will next be given with reference to FIG. 1. The semiconductor device 1 has a semiconductor substrate (for example, silicon substrate) 9 of heavily-doped n (n⁺) conductivity type, and also has a plurality of first semiconductor regions 13 of n type and a plurality of second semiconductor regions 15 of p type, which are laid out on a top surface 11 of the substrate 9. The n type is one example of the first conductivity type, while the p type is an example of the second conductivity type.

The n⁺-type semiconductor substrate 9 functions as a drain region(s). The plurality of first semiconductor regions 13 may be fabricated by a process having the steps of forming an n-type single-crystalline silicon layer on the surface 11 of semiconductor substrate 9 and then defining therein a plurality of trenches 17. The second semiconductor regions 15 are p-type single-crystalline silicon layers that are buried by epitaxial growth techniques in respective ones of the trenches 17: that is, the regions 15 are epitaxial growth layers. In this way, the cell formation part 3 includes the first n-type semiconductor regions 13 and the second p-type semiconductor regions 15, which are disposed on the surface 11 of semiconductor substrate 9. Each region 13 functions as a drift region.

The regions 13 and 15 have a column-like shape. With these columnar regions, what is called the “super junction” structure is constituted. Explaining in greater detail, the first n-type semiconductor regions 13 and the second p-type semiconductor regions 15 are alternately disposed repeatedly in the direction parallel to the surface 11 of semiconductor substrate 9 in such a manner as to enable complete depletion of these regions 13, 15 at the time the power semiconductor device 1 is driven to turn off. The language “the direction parallel to the surface 11 of semiconductor substrate 9” may be reworded by a “lateral direction.” In addition, the wording “alternately and repeatedly” may be rephrased by “periodically.” With such the super-junction structure, it is possible to simultaneously achieve both low turn-on (“ON”) resistance and higher breakdown voltage characteristics of the power MOSFET.

The regions 13 and 15 have portions that are on the opposite side to the semiconductor substrate 9, at certain ones of which a plurality of p-type base regions (sometimes called the body regions) 19 are formed at prespecified intervals or layout pitches. The base regions 19 are located on the second semiconductor regions 15 and are greater in width than these regions 15. In each base region 19, an n⁺-type source region 21 is formed. More specifically, between a central portion and an edge portion of the base region 19, the source region 21 extends inward from a top surface of base region 19. At the center of base region 19, a p⁺-type contact region 23 is formed for use as an electrical contact conductor of the base region 19.

Above the edge portion of each base region 19, a gate electrode 27 made for example of polysilicon is formed with a gate dielectric insulating film 25 being sandwiched between them. The edge portion of base region 19 functions as a channel region 29. Between the gate electrode 27 and its associative first semiconductor region 13, a dielectric insulator film 31 is formed, which is thicker than the gate insulator film 25. An interlayer dielectric (ILD) film 33 is formed to cover the gate electrode 27.

Through-holes are defined in the ILD film 33. Each through-hole is for exposure of a contact region 23 and a portion of the source region 21 on the contact region 23 side. At the through-holes, common-coupled source electrodes 35 are formed. Additionally, a drain electrode 37 made for example of copper or aluminum is attached to an overall area of the back surface of the semiconductor substrate 9.

One MOSFET cell 39 is generally made up of a second semiconductor region 15, half portions of a couple of first semiconductor regions 13.on the both sides of the region 15, a base region 19 residing at a position corresponding to these regions, a source region 21, and a gate electrode 27. In the cell formation part 3, a large number of MOSFET cells 39 are orderly arranged.

Next, a structure of the chip end part 5 will be explained with reference to FIG. 2. On the top surface 11 of the semiconductor substrate 9, an n-type single-crystalline silicon layer 41 is disposed. The first semiconductor regions 13 are fabricated by providing trenches 17 in the single-crystal silicon layer 41 that has been disposed in the cell formation part 3.

In the monocrystal silicon layer 41 of the end part 5, three electrically floating guard rings 7 are disposed. These include an guard ring 7-1 which is located at the innermost position, a guard ring 7-2 that is outside of it, and a guard ring 7-3 placed on the outermost side. These guard rings 7 are fabricated by burying p-type epitaxial growth layers in the trenches 43. Owing to this, each guard ring 7 has a substantially flat sidewall.

The guard rings 7 are specifically designed so that these become gradually (1) shallower, (2) narrower in width, and (3) wider in distance or interval of neighboring guard rings as they shift in position from the inside toward the outside. Explaining in greater detail, the guard rings 7 do not reach the surface 11 of the semiconductor substrate 9. Guard rings 7 are designed to have specific depth values which satisfy a specific relationship which follows: D1>D2>D3, where D1 is the depth of guard ring 7-1, D2 is the depth of guard ring 7-2, and D3 is the depth of guard ring 7-3. Hence, the more outside the location, the shallower the guard ring.

Regarding the width values of the guard rings 7, these are set to satisfy a relationship which follows: W1>W2>W3, where W1 is the width of the guard ring 7-1, W2 is the width of guard ring 7-2, and D3 is the width of guard ring 7-3. Hence, the more outside the position, the less the guard ring width. Furthermore, the interval or layout pitch of neighboring guard rings is arranged to satisfy the following relationship: S1<S2, where S1 is the pitch of the guard ring 7-1 and guard ring 7-2, and S2 is the pitch of guard rings 7-2 and 7-3. As a consequence, the more outside the location, the greater the guard ring layout pitch.

In a surface portion of the single-crystal silicon layer 41 that is outside the guard ring 7-3, an N⁺-type channel stopper region 45 is formed. An interval between this region 45 and the guard ring 7-3 is greater in value than the layout pitch S2. Region 45 is shallower than guard ring 7-3.

On the single-crystalline silicon layer 41 a dielectric film 31 is formed to cover the three guard rings 7. An interlayer dielectric (ILD) film 47 is formed thereon. A through-hole for exposure of the channel stop region 45 is defined in the dielectric film 31 and ILD film 47. In this through-hole a channel stopper electrode 49 is buried.

(Semiconductor Device Operation)

An operation of the power semiconductor device 1 will be explained using FIG. 1. In this operation, the source region 21 and base region 19 of each MOSFET cell 39 are coupled to ground. In addition, a prespecified voltage of the positive polarity is applied through the drain electrode 37 to the semiconductor substrate 9 for use as the drain region. Additionally the same positive voltage as that for the drain electrode 37 is also applied to the channel stopper electrode 49.

When letting the power semiconductor device 1 perform a turn-on operation, a positive voltage with a specified potential level is applied to the gate electrode 27 of each MOSFET cell 39. This results in formation of an n-type inversion layer in its channel region 29. Electrons behave to leave a source region 21 and then pass through this inversion layer for injection into a corresponding one of the first n-type semiconductor regions 13 that is a drift region, and then reach the semiconductor substrate 9 that is the drain region. Thus a current flows from substrate 9 to source region 21.

On the contrary, when causing the semiconductor device 1 to turn off, appropriately control the voltage being applied to the gate electrode 27 of each MOSFET cell 39 in such a way that this gate electrode 27 becomes less than or equal in potential to the source region 21. Whereby, the inversion layer of the channel region 29 disappears, resulting in interruption or halt of the injection of electrons from the source region 21 to the n-type first semiconductor region 13. Thus, no current flows from the semiconductor substrate 9 for use as the drain region toward the source region 21. And, in the turn-off event, the regions 13 and 15 are almost completely depleted by the creation of a depletion layer laterally extending from a p-n junction 51, which is formed by first and second semiconductor regions 13 and 15. This permits the semiconductor device 1 to retain the breakdown voltage required.

(Main Effects of First Embodiment)

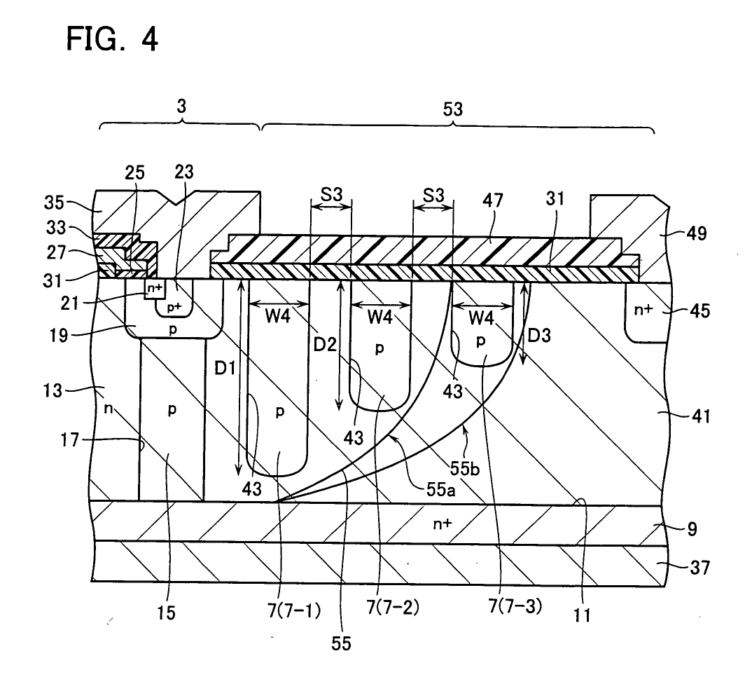

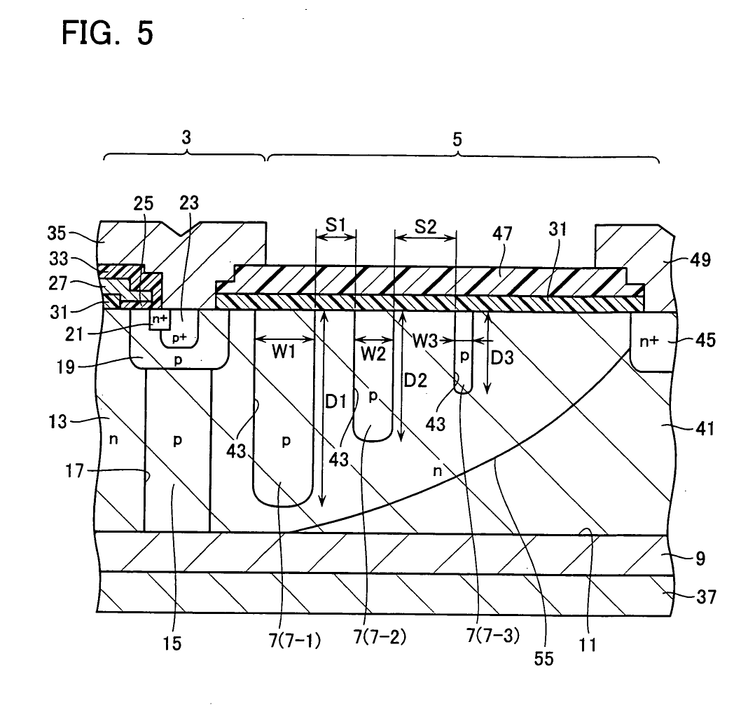

Some major effects and advantages of the first embodiment will be explained while comparing it to a comparative form. FIGS. 4 and 5 are partial cross-sectional views of the terminate end parts of semiconductor devices in the turnoff event. These are semiconductor devices for the 600-V use. Suppose that the depth of first semiconductor regions 13 is set to 60 micrometers (μm). FIG. 4 shows an end part 53 of a comparative example, while FIG. 5 depicts the end part 5 in accordance with the first embodiment, each of which diagrams corresponds to FIG. 2. A difference of the end part 53 from the end part 5 lies in the widths of guard rings 7 and the interval or layout pitch of neighboring ones thereof. More specifically, the end part 53 is such that the width W4 of each guard ring 7 is the same while letting the interval S3 of neighboring guard rings 7 be the same in value.

As shown in FIG. 4, a depletion layer 55 extends at the end part 53. However, the depletion layer 55 is insufficient in degree of extension at the end part 53 and, for the very reason, fails to reach the channel stopper region 45. This depletion layer terminates at a location between the guard ring 7-2 and guard ring 7-3 as indicated by “55a” or alternatively terminates immediately after having gone beyond the guard ring 7-3 as shown by “55b.” This results in that a curvature-enlarged portion (e.g., portion 55a or 55b) occurs in the depletion layer 55. Appreciable electric field concentration tends to take place at this portion 55a, 55b. This field concentration can cause unwanted decrease in breakdown voltage of the power semiconductor device.

In the comparative example, the extension of the depletion layer 55 still remains insufficient even when redesigning the guard rings 7 so that a guard ring near the outside is shallower than an inside guard ring. This can be said because chip designs are inappropriate in regard to both the width W and the interval S of guard rings. For example, in case the depletion layer unintentionally terminates at a location midway between the guard ring 7-2 and guard ring 7-3 as indicated by “55a” in FIG. 4, the degree of extension of the depletion layer 55 is determined depending upon the position of guard ring 7 in the end part 53 at the time the semiconductor device turns off; however, the depletion layer 55 is incapable of going beyond the outermost guard ring. 7-3 since this guard ring 7-3 is larger in width W than the others. Alternatively, in case the depletion layer 55 terminates immediately after having gone beyond the guard ring 7-3, the dispersion of potential level due to guard ring(s) 7 becomes insufficient due to the fact that the guard rings are laid out merely at equal intervals. This makes it impossible for depletion layer 55 to sufficiently extend at a location outside the outermost guard ring 7-3.

To avoid this risk, let the semiconductor device be structured to have the end part 5 as in the first embodiment shown in FIG. 5. This structure is similar to the comparative example in that the guard rings 7 are designed to become sequentially shallower as getting near to the guard ring 7 that is located outside. In addition to this “variable depth” structure design, another design is added: that is, employ at least one of (1) the structure with guard rings 7 being sequentially lessened in width as getting near to the guard ring 7 that is located outside, and (2) the structure wherein the interval between neighboring guard rings increases as getting near to the guard ring 7 that is located outside. In accordance with the first embodiment thus structured, it becomes possible for the depletion layer 55 to reach the channel stopper region 45 after having jumped all of the guard rings 7 involved. This makes it possible to permit the depletion layer 55 to exhibit a more moderate curvature. This enables preclusion of the electric field concentration at depletion layer 55. Thus it is possible to improve the breakdown voltage of the semiconductor device.

It should be noted that in this embodiment, the number of the guard rings 7 should not be limited to three-two or four guard rings are alternatively employable when the need arises.

(Semiconductor Device Fabrication Method)

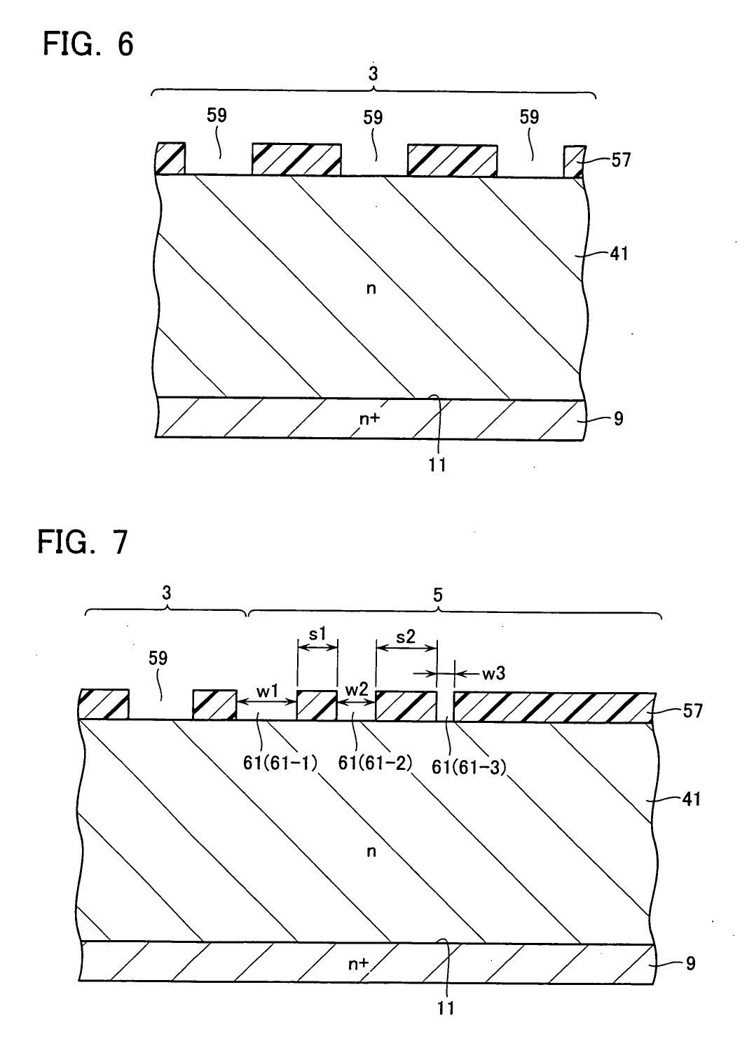

A method for fabricating the semiconductor device 1 in accordance with the first embodiment will be explained with reference to FIGS. 1, 2 and 6 to 17. FIGS. 6-17 are cross-sectional diagrams showing the fabrication method of the semiconductor device 1 shown in FIGS. 1-2 in the order of process steps thereof. In the description, the term “cell formation part” is used to mean either a region in which cells are formed or a region in which such cells will be formed.

As shown in FIGS. 6 and 7, there is prepared a semiconductor substrate 9 of n+ type with its specific resistance or “resistivity” of 3 Ocm as an example. On an entire top surface 11 of the semiconductor substrate 9, form by epitaxial growth techniques an n-type single-crystalline silicon layer 41 with its resistivity of 40 cm and a thickness of about 60 μm. The single-crystalline silicon layer 41, which is a semiconductor layer, includes a terminate end part 5 and a cell formation part 3 as surrounded by this end part 5. Next, form on the entire surface of the single-crystalline silicon layer 41 a silicon oxide film 57 (one example of the film to be processed) with a thickness of 2 μm, by using chemical vapor deposition (CVD) techniques for example.

Then, use photolithography and etching techniques to pattern the silicon oxide film 57, thereby defining predetermined openings in the silicon oxide film 57. More precisely, define at a portion corresponding to the cell formation part 3 a plurality of openings 59 that are the same in width as the second semiconductor regions 15 of FIG. 1. In contrast, at a portion corresponding to the end part 5, define a plurality of openings 61 which are specifically designed so that these are made sequentially smaller in width as they get near to the outside while at the same time letting adjacent openings gradually increase in interval or layout pitch thereof. These openings 61 have a layout pattern which is the same as that of the guard rings 7 shown in FIG. 3, and surround a portion of the silicon oxide film 57 which corresponds to the cell formation part 3.

The openings 61 include an opening 61-1 that is located on the innermost side, an opening 61-2 that resides on its outside, and an opening 61-3 that is at its further outside position. These openings have width values w1, w2 and w3, which are equal to the widths W1, W2 and W3 of the guard rings 7 of FIG. 2, respectively. In addition, a couple of neighboring openings 61-1 and 61-2 are laid out at an interval s1, which is equal to the interval S1 of neighboring guard rings 7. Similarly, another pair of adjacent openings 61-2 and 61-3 are at an interval s2, which is the same as the interval S2 of adjacent guard rings 7.

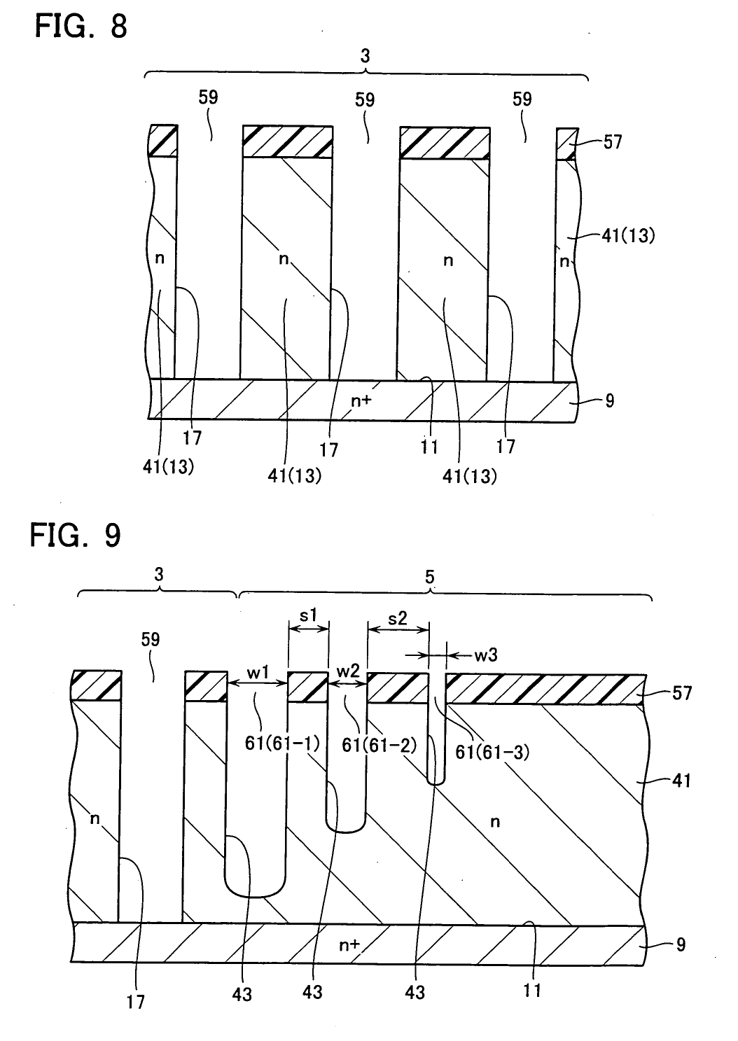

Next, as shown in FIGS. 8 and 9, selectively etch the single-crystalline silicon layer 41 by anisotropic etch techniques, while using as a mask the silicon oxide film (one example of the to-be-processed film) with the openings 59 and 61 defined therein. This results in formation of trench 17 and 43 having the structures shown in FIGS. 1 and 2. Explaining in more detail, define in the cell formation part 3 a plurality of trenches 17 with a depth large enough to reach the semiconductor substrate 9—e.g., about 60 μm—at specified intervals in a direction parallel to the surface 11 of semiconductor substrate 9. By providing the multiple trenches 17 in the single-crystalline silicon layer 41 in this way, a plurality of first semiconductor regions 13 are thus formed. The length of a time as taken for the above-noted etching process is determinable with the time consumed for trenches 17 to reach the semiconductor substrate 9 as a reference.

On the other hand, the selective etching results in trenches 43 being defined in the end part 5. These trenches are made shallower sequentially as they get near to the trench that is located outside. This is due to what is called the micro-loading effect for causing trenches to become shallower with a decrease in mask opening width. See FIG. 18, which is a pictorial representation of a partial cross-section of a silicon layer 63 which exhibits the micro-loading effect. As shown herein, trenches 65 become smaller in depth with a decrease in width of trench 65, which corresponds to the mask opening width.

Also note that since the trenches 43 are formed with the silicon oxide film 57 as a mask, a trench 43 that is located at an outside position is less in width than those at its inside positions, while letting neighboring trenches 43 become larger in layout interval.

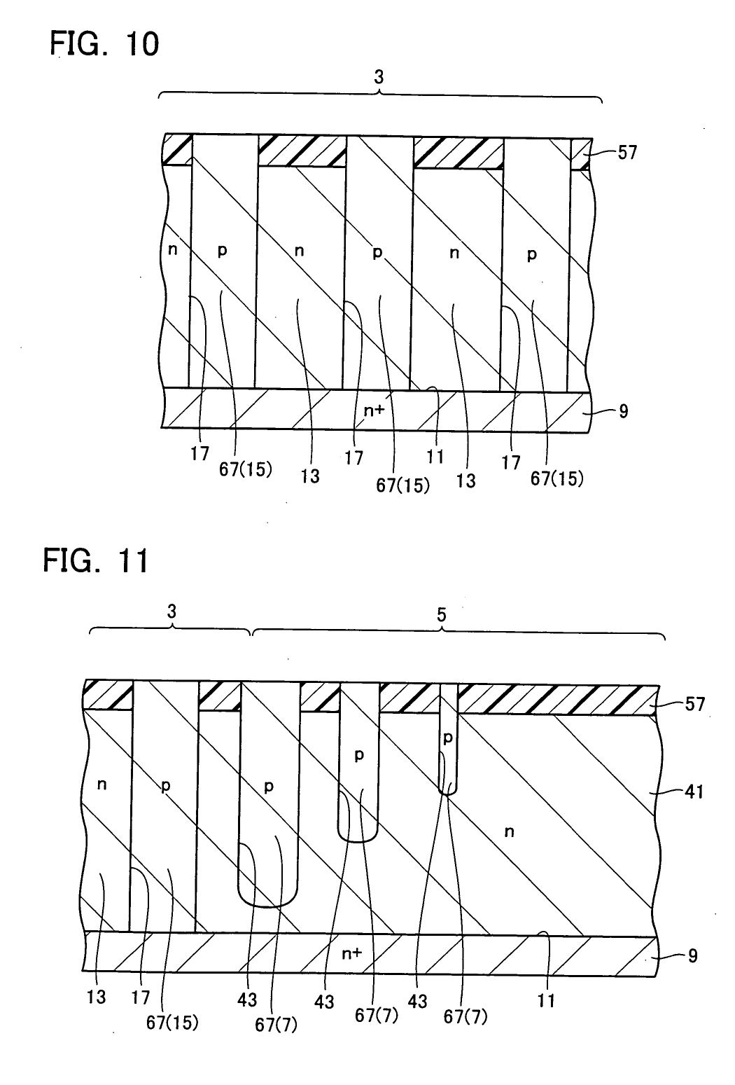

Next, as shown in FIGS. 10 and 11, use a mixture of silane and chlorine-based gases to cause a single-crystalline silicon layer to epitaxially grow within the individual trench 17, 43, which layer has its p-type impurity concentration of about 1×10¹⁵ atoms per cubic centimeter (cm⁻³), by way of example. Whereby, the trench 17, 43 is filled with an epitaxial growth layer 67 as buried therein, which is comprised of a single-crystalline silicon layer. An epitaxial growth layer 67 that was buried in trench 17 becomes the second semiconductor region 15, whereas an epitaxial growth layer 67 buried in trench 43 is for use as guard ring 7. Thus it is possible to form in the cell formation part 3 an alternate array of first semiconductor regions 13 and second semiconductor regions 15 in the direction parallel to the surface 11 of semiconductor substrate 9 while at the same time forming a plurality of guard rings 7 in the end part 5.

It should be noted that although in the above embodiment the opening defining step and the trench forming step plus the epitaxial growth step are simultaneously implemented in both the cell formation part 3 and the end part 5, any one of these steps may alternatively be done prior to the others. An example is that the trenches 17 rather than the openings 61 shown in FIG. 7 are first formed in the cell formation part 3, followed by the step of burying the epitaxial growth layer 67 in each trench 17. Thereafter, oxidation is performed to fill the opening 59. Then, define openings 61 in the silicon oxide film 57 of the end part 5. Next, define trenches 43 in end part 5, then, bury the epitaxial growth layer 67 in trenches 43. With this approach, it is possible to optimize both the impurity concentration of second semiconductor regions 15 and that of guard rings 7.

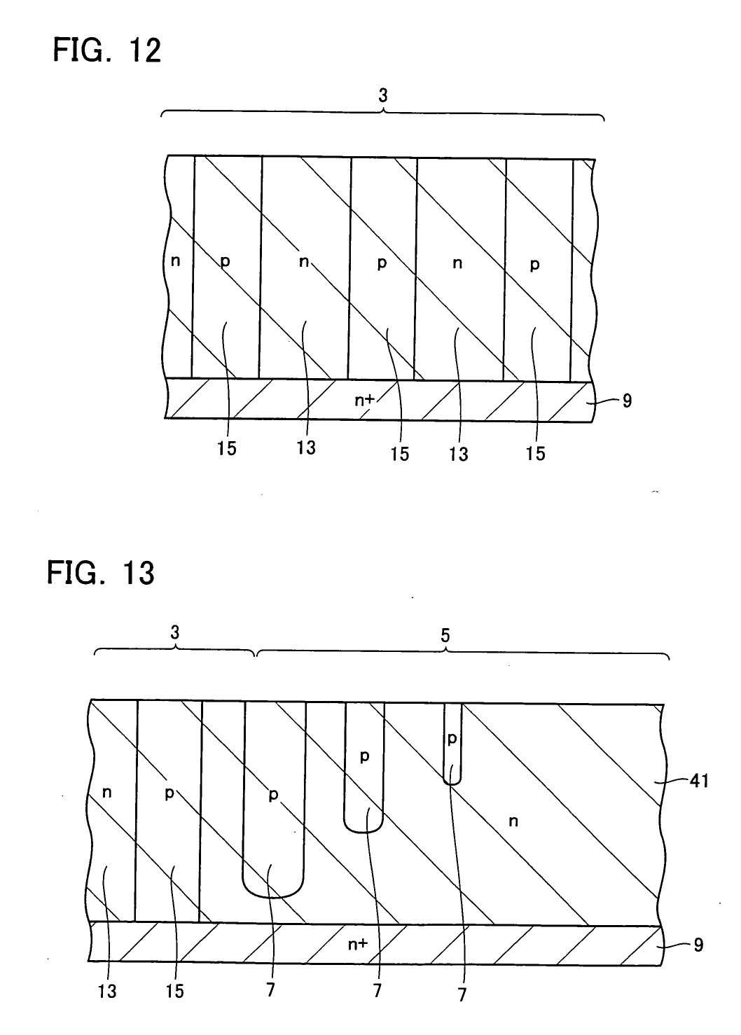

Next, remove the silicon oxide film 57 by wet etching treatment using NH₄F as an example. Then, as shown in FIGS. 12 and 13, apply mirror surface polishing to the resultant exposed surface (including the surfaces of first semiconductor regions 13, second semiconductor regions 15, guard rings 7 and single-crystalline silicon layer 41).

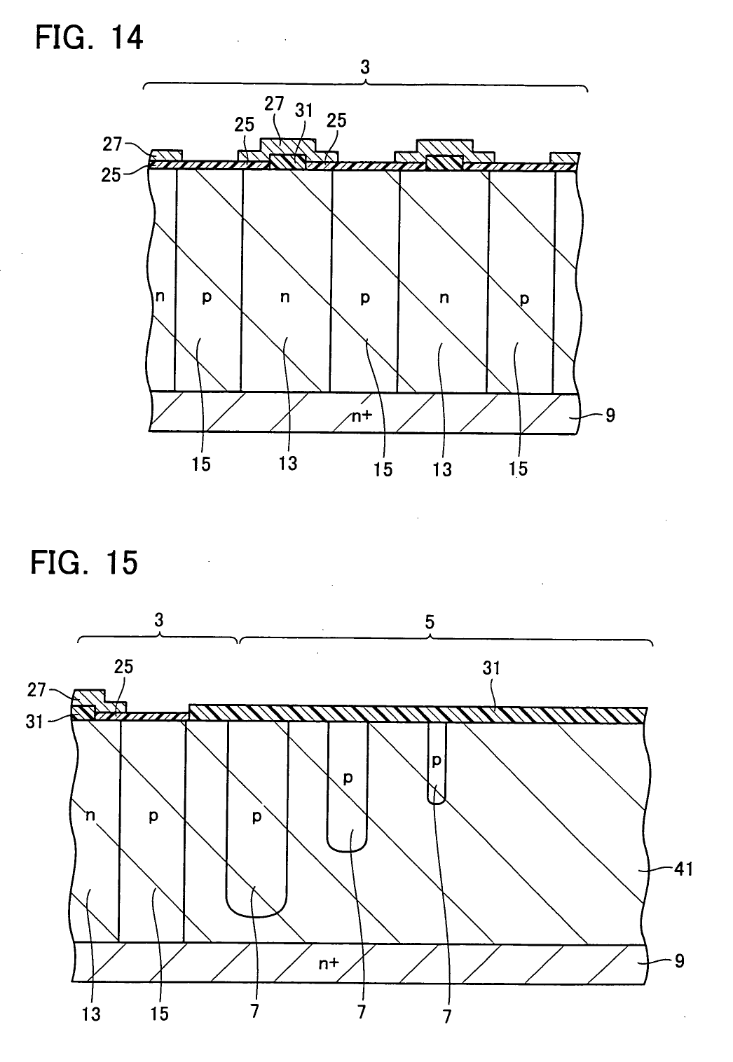

Thereafter, as shown in FIGS. 14 and 15, form in the cell formation part 3 and end part 5 a dielectric film 31 (e.g., silicon oxide film) with specified patterning applied thereto. By this patterning, the dielectric film 31 is selectively formed on the first semiconductor regions 13 in the cell formation part 3. The dielectric film 31 is formed on an overall surface of the end part 5.

Next, thermal oxidation is applied to certain portions overlying those regions on which the dielectric film 31 is not formed, thereby forming a gate insulator film 25 with a thickness of 100 nanometers (nm) for example. Then, form a polysilicon film by CVD on the overall surfaces of the cell formation part 3 and end part 5. This polysilicon film is then patterned to have a prespecified pattern, thereby forming gate electrodes 27.

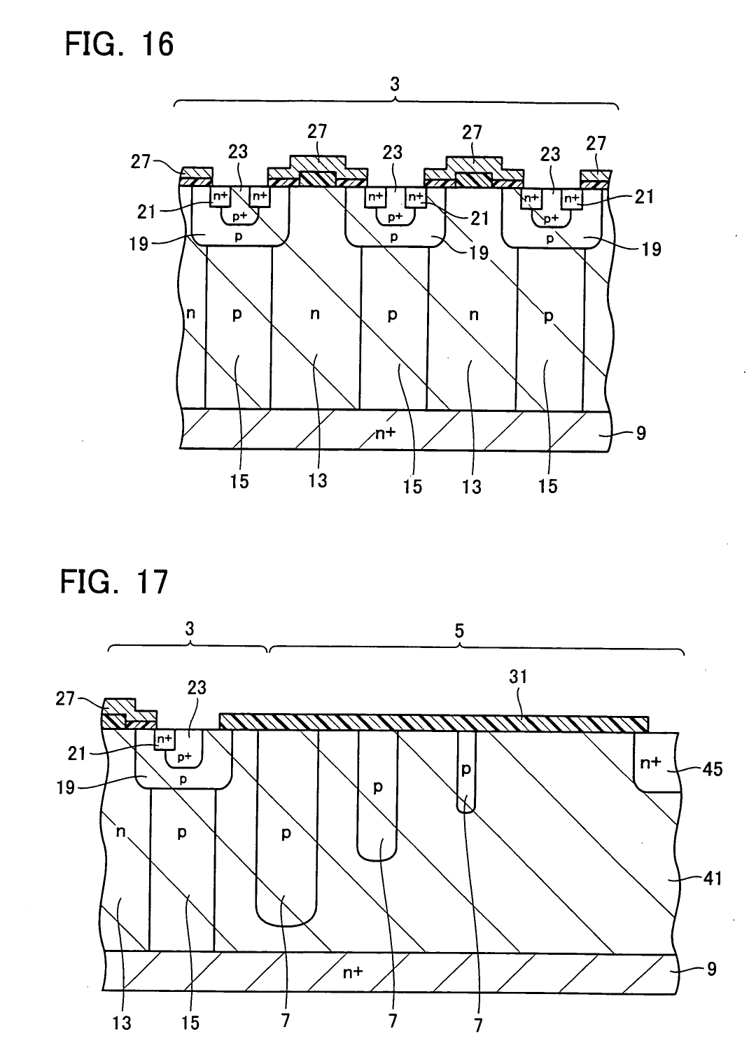

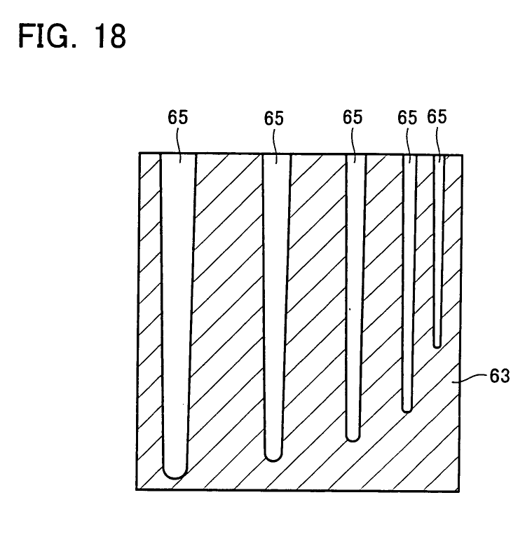

As shown in FIGS. 16 and 17, implant impurity ions into the cell formation part 3 with the gate electrodes 27 and the dielectric film 31 as a mask therefor. Then, thermally diffuse the doped impurities to thereby form p⁺-type base regions 19 in the cell formation part 3. For example, some major conditions of the ion implantation are as follows: the ion species is boron; the acceleration voltage is set at 60 kilo-electronvolts (keV); and, the dose is at 5×10¹³ cm². Exemplary conditions of the thermal diffusion are such that the diffusion is done at a temperature of 1100° C. for 60 minutes in the atmosphere of a nitrogen gas.

Subsequently, form in the cell formation part 3 and end part 5 a resist film (not shown) having openings above those regions in which source regions 21 are to be formed and the region for formation of the channel stopper region 45. Then, with this resist as a mask, remove away the gate insulator film 25 and dielectric film 31. Next, with the resist and gate electrodes 27 as a mask, perform ion implantation into the cell formation part 3 and end part 5, followed by execution of thermal diffusion. By these processes, form in each base region 19 an n⁺-type source region 21 and also form a channel stopper region 45 in the end part 5. For instance, the conditions of such ion implantation are as follows: the ion species is arsenic, the acceleration voltage is at 40 keV, and the dose is 1×10¹⁵ cm⁻². Typically the thermal diffusion is done at a temperature of 1000° C. for 20 minutes in the atmosphere of an oxygen gas.

After having formed the source regions 21, form a resist film which has openings in certain regions in which contact regions 23 are to be formed. With this resist as a mask, ion implantation and thermal diffusion are done to the base regions 19 to thereby form p⁺-type contact regions 23.

As shown in FIGS. 1 and 2, atmospheric pressure CVD (LPCVD) is performed to sequentially form, on the entire surfaces of the cell formation part 3 and end part 5, a silicon oxide film having a thickness of about 0.2 μm and a boro-phospho-silicate glass (BPSG) film with a thickness of about 0.5 μm, by way of example. These films become the interlayer dielectric (ILD) film 33 in the cell formation part 3 while becoming the ILD film 47 in the end part 5. Next, use known methods to form source electrodes 35 to be connected to the source regions 21, gate extension wiring leads (not shown) for interconnection to the gate electrodes 27, and a channel stopper electrode 49 to be connected to the channel stopper region 45. These electrodes are typically made of aluminum. Finally, form a drain electrode 37 made for example of aluminum on the back surface of the semiconductor substrate 9. With the method having the process steps stated above, the power semiconductor device 1 is thus completed.

### Second Embodiment

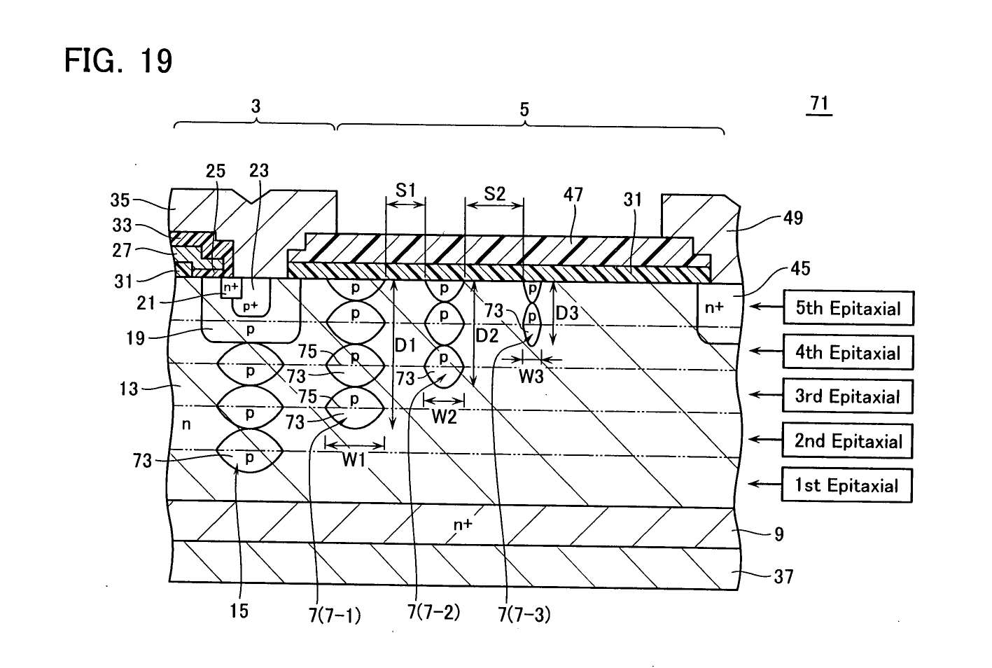

FIG. 19 is a partial cross-sectional view of the end part 5 of a power semiconductor device 71 in accordance with a second embodiment of the invention. In the first embodiment shown in FIG. 2, the multiple trenches 17 and 43 are formed in the single-crystalline silicon layer 41 while letting these trenches be filled with buried epitaxial growth layers, which are opposite in conductivity type to the silicon layer 41. This results in formation of the super-junction structure in the cell formation part 3 while at the same time forming guard rings 7 in the end part 5.

By contrast, the second embodiment shown in FIG. 19 is with repeated execution of a necessary number (five times in the second embodiment) of process steps of forming an n-type single-crystalline silicon layer by epitaxial growth techniques, selectively implanting a p-type impurity into this layer, and then activating this impurity. By repeating this process, the super-junction structure is formed in the cell formation part 3 while forming guard rings 7 in the end part 5.

The second semiconductor regions 15 are such that the fabrication of p-type impurity-doped regions 73 gets started from a first epitaxial growth layer, as indicated by “1st Epitaxial”. Guard rings 7-1, 7-2 and 7-3 are such that the formation of p-type impurity regions 73 is started from “2nd Epitaxial,” “3rd Epitaxial” and “4th Epitaxial” respectively. Owing to this, the resulting guard rings 7 are made sequentially shallower as these get near to the one that is at the outermost position.

The guard rings 7 of the second embodiment are the same as those of the first embodiment in width values (W1, W2, W3) and in depth values (D1, D2, D3) and also in intervals (S1, S2) of neighboring guard rings. Thus, the second embodiment also offers its effects and advantages that are substantially the same as those discussed in the above section titled “Main Effects of First Embodiment.”

It should be noted that the first embodiment offers its unique advantages superior than the second embodiment as will be discussed below. In the second embodiment, the guard rings 7 are formed by repeated execution of the p-type impurity injection and the activation of this impurity, so the following phenomena (1) and (2) would take place.

(1) The p-type impurity regions 73 are variable in the laterally extending degree so that an impurity region placed at a lower level becomes larger in lateral extension than an impurity region at an upper level. Accordingly, the guard ring 7-1 must have a p-type impurity region 73 that is large in lateral extension degree. The guard rings 7 are arranged so that the interval of neighboring ones thereof becomes smaller (interval S1<interval S2) as the position of a guard ring 7 gets near to the inside. Thus, due to the phenomenon stated above, the guard ring 7-1 and guard ring 7-2 can sometimes come into contact with each other. In order to avoid such unwanted contact, it is hardly possible in some cases to attain the intended size optimization of the guard ring 7-1 that resides at an inside position.

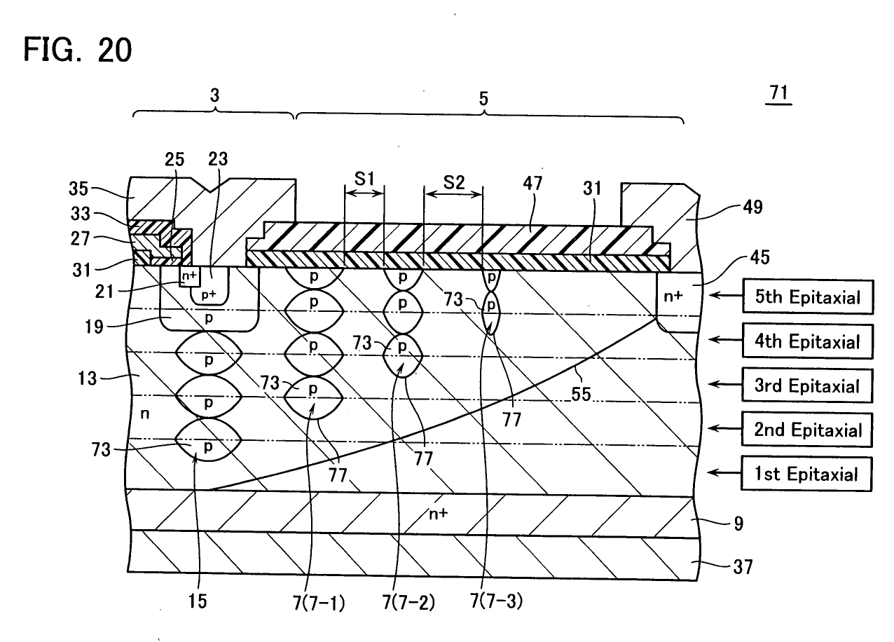

(2) The impurity concentration of p-type impurity region 73 becomes the highest at an interface 75 between stacked epitaxial layers, resulting in the impurity concentration becoming lower with an increase in vertical distance from the interface 75. Such impurity concentration irregularity or “ununiformity” can sometimes badly serve as a bar to free extension of a depletion layer. This will be explained using FIG. 20. FIG. 20 corresponds to FIG. 19 and shows a state that a depletion layer 55 extends. Assume here that the depletion layer 55 has its potential of 600V. Also assume that the guard rings 7-1, 7-2 and 7-3 are 150V, 300V and 450V in potential at their distal ends 77, respectively. In this state, suppose that the deletion layer 55 fully extends resulting in its curvature becoming moderate. The potential level of guard ring 7's distal end determines the extension of the depletion layer 55. The impurity concentration ununiformity of the above-noted p-type impurity region 73 can cause unwanted potential variation at the distal end 77. This results in the depletion layer 55 failing to sufficiently extend in some cases.

In contrast, the first embodiment shown in FIG. 2 is free from the risk of occurrence of the above-noted phenomena (1) and (2) because the guard rings 7 are formed by burying the p-type epitaxial growth layer in each trench 43. Thus it is possible to optimize the size of the guard ring 7-1 that resides at the inside position while at the same time allowing the depletion layer 55 to extend sufficiently.

It is noted here that although the first and second embodiments are power semiconductor devices having the super-junction structure, the principles of this invention may alternatively be applicable to conventional power semiconductor devices without the above-noted structure. Such conventional power semiconductor devices do not have the structure with the second semiconductor regions 15 of p type being formed in trenches 17, but have a structure in which p-type base regions 19 are formed in an n-type single-crystalline silicon layer 41.

Also note that the first and second embodiments are arranged so that the MOSFET cells 39 are formed as power semiconductor elements in the cell formation part 3. However, this invention is not exclusively limited to such specific embodiments: it is also permissible to form therein other types of power semiconductor elements including, but not limited to, bipolar transistors, insulated-gate bipolar transistors (IGBTs), and Schottky barrier transistors (SBTs).

Although the first and second embodiments are of the MOS type including gate insulator films made of silicon oxides, this invention is not limited thereto and may also be applicable to other ones of the metal insulator semiconductor (MIS) type having gate insulator films made of insulating materials other than the silicon oxides, such as for example insulative films with high dielectric constants.

While the semiconductor devices in accordance with the first and second embodiments are the ones using silicon semiconductor architectures, the invention may also be applied to those semiconductor devices employing other kinds of semiconductor materials, such as for example silicon carbides and gallium nitrides.

What is claimed is:

1. A semiconductor device comprising:
a semiconductor layer including a terminate end part and a cell formation part as surrounded by this end part; and
a plurality of guard rings each being formed at the end part to surround said cell formation part and being arranged to become shallower and smaller in width as getting near to a guard ring placed outside.

2. The device according to claim 1, wherein the guard rings are made larger in interval between neighboring ones thereof as getting near to the guard ring placed outside.

3. The device according to claim 1, wherein said plurality of guard rings have a structure with an epitaxial growth layer being buried in a plurality of trenches as provided at said end part.

4. The device according to claim 1, wherein
said semiconductor layer is disposed above a surface of a semiconductor substrate of a first conductivity type,
said cell formation part includes a plurality of first semiconductor regions of the first conductivity type and a plurality of second semiconductor regions of a second conductivity type as disposed above the surface of said semiconductor substrate, and
in said cell formation part, said plurality of first semiconductor regions and said second semiconductor regions are alternately repeatedly laid out in a direction parallel to the surface of said semiconductor substrate.

5. The device according to claim 4, wherein said plurality of first semiconductor regions have a structure formed by providing a plurality of first trenches in a single-crystalline semiconductor layer of the first conductivity type as disposed above the surface of said semiconductor substrate,
said plurality of second semiconductor regions have a structure with an epitaxial growth layer of the second conductivity type being buried in said plurality of first trenches, and
said plurality of guard rings have a structure with an epitaxial growth layer of the second conductivity type being buried in a plurality of second trenches as provided at said end part.

6. The device according to claim 1, wherein said end part includes a channel stopper region at a further outside position of said plurality of guard rings.

7. The device according to claim 1, wherein said cell formation part includes one or more power semiconductor elements.

8. The device according to claim 4, wherein said cell formation part includes one or more power semiconductor elements having a super junction structure, said plurality of first semiconductor regions and said second semiconductor regions constituting said super junction structure.

9. A semiconductor device comprising:
a semiconductor layer including a terminate end part and a cell formation part as surrounded by this end part; and
a plurality of guard rings each being formed at the end part to surround said cell formation part and being arranged to become shallower and larger in interval between neighboring ones thereof as getting near to a guard ring placed outside.

10. The device according to claim 9, wherein said plurality of guard rings have a structure with an epitaxial growth layer being buried in a plurality of trenches as provided at said end part.

11. The device according to claim 9, wherein
said semiconductor layer is disposed above a surface of a semiconductor substrate of a first conductivity type,
said cell formation part includes a plurality of first semiconductor regions of the first conductivity type and a plurality of second semiconductor regions of a second conductivity type as disposed above the surface of said semiconductor substrate, and
in said cell formation part, said plurality of first semiconductor regions and said second semiconductor regions are alternately repeatedly laid out in a direction parallel to the surface of said semiconductor substrate.

12. The device according to claim 11, wherein said plurality of first semiconductor regions have a structure formed by providing a plurality of first trenches in a single-crystalline semiconductor layer of the first conductivity type as disposed above the surface of said semiconductor substrate,
said plurality of second semiconductor regions have a structure with an epitaxial growth layer of the second conductivity type being buried in said plurality of first trenches, and
said plurality of guard rings have a structure with an epitaxial growth layer of the second conductivity type being buried in a plurality of second trenches as provided at said end part.

13. The device according to claim 9, wherein said end part includes a channel stopper region at a further outside position of said plurality of guard rings.

14. The device according to claim 9, wherein said cell formation part includes one or more power semiconductor elements.

15. The device according to claim 11, wherein said cell formation part includes one or more power semiconductor elements having a super junction structure, said plurality of first semiconductor regions and said second semiconductor regions constituting said super junction structure.

16. A method for fabricating a semiconductor device comprising:
forming a to-be-processed film to be processed into a mask on a surface of a semiconductor layer including a terminate end part and a cell formation part as surrounded by this end part;
forming at a portion of said to-be-processed film corresponding to said end part a plurality of openings surrounding a portion of said to-be-processed film corresponding to said cell formation part and being made smaller in width as getting near to an opening placed outside;
selectively etching said semiconductor layer while letting said to-be-processed film with said plurality of openings formed therein be as a mask to thereby form in said end part a plurality of trenches being made shallower and smaller in width as getting near to a trench placed outside; and
burying an epitaxial growth layer in said plurality of trenches to thereby form in said end part a plurality of guard rings.

17. The method according to claim 16, wherein said plurality of openings are made larger in interval of neighboring ones thereof as getting near to an opening placed outside.

18. The method according to claim 16, wherein said semiconductor layer is a single-crystalline semiconductor layer of a first conductivity type as disposed above a surface of a semiconductor substrate,
in said forming a plurality of openings, a plurality of other openings are formed at the portion of said to-be-processed film corresponding to said cell formation part,
in said selectively etching said semiconductor layer to form a plurality of trenches, a plurality of other trenches causing a portion between neighboring trenches to become a first semiconductor region are formed in said cell formation part, and
in said burying an epitaxial growth layer to form a plurality of guard rings, said epitaxial growth layer of a second conductivity type is buried in said plurality of other trenches to thereby form in said cell formation part a plurality of second semiconductor regions as alternately repeatedly laid out with said first semiconductor regions in a direction parallel to the surface of said semiconductor substrate.

19. The method according to claim 16, wherein
said semiconductor layer is a single-crystalline semiconductor layer of a first conductivity type as disposed above a surface of a semiconductor substrate, and
said method further comprises, before or after said forming a plurality of openings and said selectively etching said semiconductor layer to form a plurality of trenches and said burying an epitaxial growth layer to form a plurality of guard rings:
forming a plurality of other openings at the portion of said to-be-processed film corresponding to said cell formation part;
selectively etching said semiconductor layer while letting said to-be-processed film with said plurality of other openings formed therein be as a mask to thereby form in said cell formation part a plurality of other trenches causing a portion between neighboring trenches to become a first semiconductor region; and
burying in said plurality of other trenches an epitaxial growth layer of a second conductivity type to thereby form in said cell formation part a plurality of second semiconductor regions as alternately repeatedly laid out with said first semiconductor regions in a direction parallel to the surface of said semiconductor substrate.

20. The method according to claim 16, further comprising:
forming one or more power semiconductor elements in said cell formation part.
